(19) United States
(12) Patent Application Publication
(10) Pub. No.: US 2023/0278088 A1
(43) Pub. Date: Sep. 7, 2023

(54) METHOD FOR PRODUCING MULTI-WALLED TUBES, AND MULTIWALLED TUBE

(71) Applicant: TI Automotive (Heidelberg) GmbH, Heidelberg (DE)

(72) Inventors: Andreas STAHN, Rauenberg (DE); Georg WEICK, Plankstadt (DE)

(21) Appl. No.: 18/020,039

(22) PCT Filed: Aug. 10, 2021
(86) PCT No.: PCT/IB2021/057380

§ 371 Date: Feb. 6, 2023

(30) Foreign Application Priority Data
Aug. 10, 2020 (EP) 20190256.6

(51) Int. Cl. B21C 37/09; C23C 14/16; C23C 14/56; C23C 16/06; C23C 16/54; C23C 4/08; C23C 4/134; C23C 4/137; C23C 4/16; C23C 4/18

(52) U.S. Cl. CPC B21C 37/09; C23C 14/16; C23C 14/562; C23C 16/06; C23C 16/545; C23C 4/08; C23C 4/134; C23C 4/137; C23C 4/16; C23C 4/18

(57) ABSTRACT

The disclosure relates to a method for producing multi-walled tubes, in which a metal strip is rolled up to form the multi-walled tube. The metal strip has at least one steel layer, and at least one solder layer is applied to the steel layer. The solder layer consists at least in part of metal. According to the disclosure, the solder layer is applied to the steel layer by plasma coating.

### RELATED APPLICATIONS

This application is a 35 U.S.C. § 371 national phase of PCT International Application No. PCT/IB2021/057380, filed Aug. 10, 2021, which claims benefit of European Application No. 20190256.6, filed Aug. 20, 2020, the contents of which are incorporated herein by reference in their entirety.

### FIELD

The disclosure relates to a method for producing multi-walled tubes, in which a metal strip is rolled up to form the multi-walled tube, the metal strip having at least one steel layer, and at least one solder layer being applied to the steel layer, and the solder layer consisting at least in part of metal and preferably consisting at least substantially of metal. To produce the metal strip, the process starts from a steel strip, which forms the steel layer and undergoes the corresponding coating and is then rolled up to form the multi-walled tube. The disclosure also relates to a multi-walled tube having such a rolled-up metal strip.

### BACKGROUND

Methods of the above-described type are well-known in practice. The deposition of the solder layer is implemented with the aid of a galvanic process. In this case, however, we have found that sufficient adhesion is generally only achievable with cyanide-containing electrolyte baths. It is self-evident that the use of highly toxic cyanides is associated with considerable disadvantages. Moreover, the galvanic process is complex and expensive, and complex settings of the process parameters are necessary. The individual method steps (preparing the electrolyte bath, drying, cleaning etc.) are also time-consuming. Furthermore, the disposal of remaining residues is problematic. In the known measures, in order to apply a copper layer as the solder layer, a nickel layer must laboriously be interposed between the steel layer and the copper layer. Nickel is also classified as harmful to health. In this respect, there is a need for improvement.

### SUMMARY

In view of this, the technical problem addressed by the disclosure is that of specifying a method of the above-described type which allows the metal strip or steel strip to be coated with a solder layer in a simple, cost-effective and less complex manner and also has fewer disadvantages from an environmental and health standpoint. The disclosure also addresses the technical problem of specifying a corresponding multi-walled tube.

To solve this technical problem, the disclosure first teaches a method for producing multi-walled tubes, in which a metal strip is rolled up to form the multi-walled tube, the metal strip having at least one steel layer, at least one solder layer being applied to the steel layer, the solder layer consisting at least in part of metal and preferably consisting at least substantially of metal, wherein the solder layer is applied to the steel layer by plasma coating.

As the starting strip or starting layer for producing the metal strip according to the disclosure, a steel strip or a steel layer is thus used, which is provided with the further coating. Before the solder layer is applied, the steel strip or the steel layers are expediently cleaned. A preferred embodiment, which is particularly significant within the scope of the disclosure, is characterized in that the surface of the steel strip or steel layer to be coated is cleaned by means of plasma treatment. Expediently, this cleaning is carried out using the preferably used plasma coating device described below. In this case, a plasma jet or a plasma flame is preferably applied to the surface of the steel strip or steel layer to be cleaned. This cleaning method has proven particularly effective within the scope of the disclosure.

A very recommended embodiment of the disclosure is characterized in that the solder layer consists at least in part of copper. Preferably, the solder layer consists fully of copper or substantially of copper. In principle, other metals can also be used for the solder layer.

Within the scope of the disclosure, the embodiment of the disclosure is particularly significant in which the solder layer—in particular the copper layer—is applied to the steel layer or steel strip without the interposition of a further metal layer —in particular without the interposition of a nickel layer. In this respect, the disclosure is based on the finding that, thanks to the plasma coating according to the disclosure, a nickel layer can be omitted without problems and sufficient adhesion of the solder layer can still be achieved. This has the advantage that the environmental disadvantages associated with the nickel layer can also be avoided.

Within the scope of the disclosure, the steel layer or steel strip has a thickness of 100 to 600 μm, in particular of 200 to 400 μm. According to a particularly recommended embodiment of the disclosure, the solder layer—in particular the copper layer—is applied to the steel layer or steel strip by plasma coating with a thickness of 1 to 50 μm, preferably of 2 to 20 μm and in particular of 3 to 10 μm. Expediently, the steel layer is thicker than the solder layer and in particular at least five times, preferably at least seven times, and preferably at least ten times as thick as the solder layer.

Within the scope of the disclosure, the coating or the coating with the solder layer takes place without the use of cyanides, and, also within the scope of the disclosure, the coating or the coating with the solder layer takes place without the use of nickel. In this respect, the disclosure is based on the finding that the disadvantageous cyanide-containing electrolyte baths can be completely omitted when the plasma coating according to the disclosure is carried out. The disclosure is also based on the finding that an interposed nickel layer between the steel layer and the solder layer or between the steel layer and the copper layer is also not necessary. The disclosure therefore has considerable advantages in terms of health aspects and environmental aspects.

A particularly preferred embodiment of the method according to the disclosure is characterized in that the plasma coating is carried out at normal pressure or atmospheric pressure. This embodiment is characterized by simplicity and low complexity. Nevertheless, it is also possible to carry out the plasma coating under different pressure conditions, for example in a vacuum.

Within the scope of the disclosure, the plasma coating is carried out as a physical vapour deposition and/or as a chemical vapour deposition. A plasma coating device is expediently used to apply the plasma coating. Within the context of the disclosure, the material for the solder layer—in particular the copper material for the solder layer—is supplied in the plasma coating device in powder form. Expediently, the material for the solder layer—in particular the copper material for the solder layer—is converted into the gas phase in the plasma coating device and then deposited on the steel layer as a solder layer or copper layer. The disclosure is based on the finding that this plasma coating of the solder layer can take place in a surprisingly simple and less complex manner and that, most of all, optimal adhesion of the solder layer or copper layer to the steel layer can be achieved without the need for an interposed nickel layer.

According to a particularly preferred embodiment of the disclosure, the metal strip consisting of at least the steel layer or steel strip and the solder layer applied thereto is rolled up to form a double-walled tube. In principle, tubes with more than two walls are also possible, and such tubes can be produced by corresponding rolling up. However, a double-walled tube is particularly preferred within the scope of the disclosure.

According to a recommended embodiment, the steel layer or steel strip is coated with the solder layer—in particular with the copper layer—on both surfaces. In this case, both surfaces of the steel layer or steel strip are preferably coated with the solder layer by means of plasma coating.

Within the scope of the disclosure, the wall layers of the multi-walled tube —in particular the double-walled tube—are soldered or joined to each other by heating. According to a recommended embodiment, the metal strip is rolled up or rolled together with the aid of rollers. Furthermore, it is preferred within the scope of the disclosure for the tube then to be heated by means of an induction furnace, as a result of which the solder layer melts. In this manner, the walls of the tube can be soldered to each other and the tube correspondingly sealed.

The disclosure also relates to a multi-walled tube having a rolled-up metal strip, the metal strip having at least one steel layer or at least one steel strip and at least one solder layer applied to the steel layer or steel strip by means of plasma coating. This is particularly preferably a double-walled tube.

The disclosure is based on the finding that a very simple, cost-effective and less complex production of multi-walled or double-walled tubes is possible with the method according to the disclosure. Advantageously, no wet chemical method steps are needed and in particular no method steps with environmentally harmful substances. The method according to the disclosure is less complex than the method known from practice and explained in the introduction. Many additional and complex method steps—such as drying steps, cleaning steps and disposal steps for environmentally hazardous substances—can be avoided. Toxic substances such as cyanides can be omitted completely, and in particular the complex interposition of a nickel layer is not necessary in the method according to the disclosure. In comparison with the known method described in the introduction, less material is used overall, less energy is consumed, and therefore the costs are also lower in the method according to the disclosure. In addition to these aspects, however, the coating applied by plasma treatment also has a significantly better quality than the coatings known from practice. The solder layer or copper layer can be applied with a surprisingly high degree of homogeneity and with a specifically set thickness. This also considerably improves the soldering of the layers. Overall, the disclosure is characterized by a multiplicity of advantages. To be emphasized in particular are simplicity, low complexity and low costs.

### BRIEF DESCRIPTION OF THE DRAWINGS

The disclosure is explained in more detail below with the aid of a drawing showing only one exemplary embodiment. In the figures:

FIG. 1 schematically shows a perspective diagram of a metal strip before being rolled up to form the multi-walled tube,

FIG. 2 schematically shows a section through a double-walled tube rolled up out of the metal strip, and

FIG. 3 schematically shows a schematic diagram of a plasma coating device preferably used to carry out the method according to the disclosure.

The figures illustrate a method according to the disclosure for producing multi-walled tubes 1. Preferably and in the exemplary embodiment (see in particular FIG. 2), a double-walled tube 1 is produced using the method according to the disclosure. To this end, a metal strip 2 is rolled up to form the double-walled tube 1. Expediently and in the exemplary embodiment, the metal strip has a steel layer 3 or steel strip. Preferably and in the exemplary embodiment, a solder layer 4 of copper is applied to this steel layer 3.

### DETAILED DESCRIPTION

In the exemplary embodiment, the steel layer can have a thickness of 200 to 400 μm, and the solder layer 4 or copper layer can have a thickness of 3 to 10 μm. Preferably and in the exemplary embodiment, the steel layer 3 is much thicker than the solder layer 4 or copper layer. According to the disclosure, the coating with the solder layer 4 takes place without the interposition of a nickel layer as is known in the prior art.

According to the disclosure, the solder layer 4 or copper layer is applied to the steel layer 3 or steel strip by plasma coating. Expediently, the plasma coating is carried out at normal pressure or atmospheric pressure. Within the scope of the disclosure, the plasma coating takes place as a physical vapour deposition.

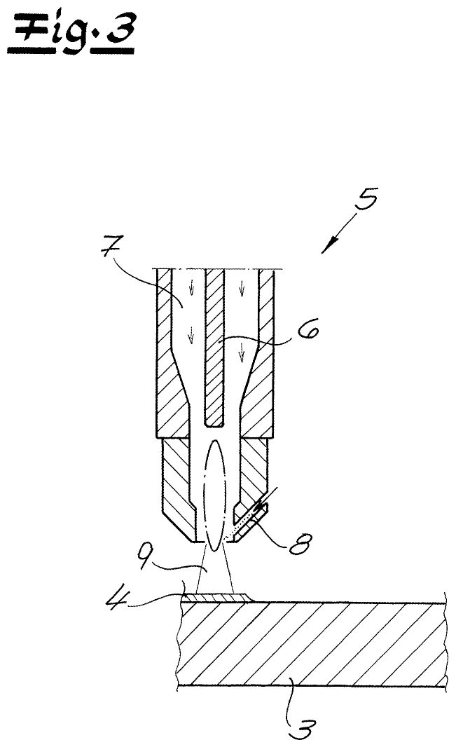

FIG. 3 shows a plasma coating device 5 suitable for the method according to the disclosure. FIG. 3 shows the electrode 6 of this plasma coating device 5 and the gas supply chamber 7. Within the scope of the disclosure, the material for the solder layer 4—in particular the copper material for the solder layer 4—is supplied in the plasma coating device 5 in powder form, more specifically, expediently and in the exemplary embodiment, is supplied through the duct 8 in powder form. Preferably and in the exemplary embodiment, the material for the solder layer 4—in particular the copper material for the solder layer 4—is converted into the gas phase in the plasma coating device 5 and then deposited on the steel layer 3 as a solder layer 4 or copper layer. The plasma jet 9 can also be seen in FIG. 3.

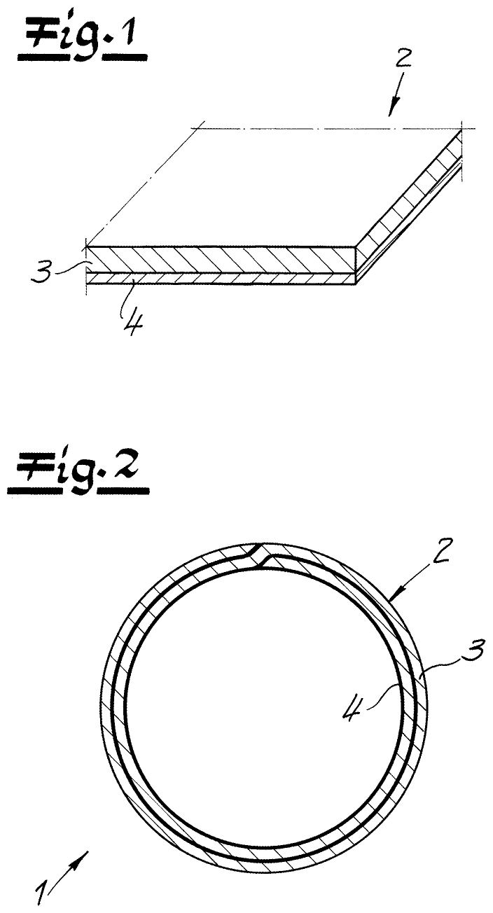

After the deposition of the solder layer 4, the coated metal strip 2 shown in FIG. 1 is obtained. This metal strip 2 is then preferably rolled up with the aid of rollers to form the double-walled tube 1 shown in FIG. 2. Within the scope of the disclosure, the tube 1 or the wall layers of the tube 1 are then soldered or joined to each other by heating. Expediently, this heating takes place in an induction furnace (not shown).

The production according to the disclosure of the multi-walled or double-walled tube 1 can advantageously be carried out without the use of cyanide-containing electrolyte baths and can advantageously also take place without the interposition of a nickel layer between the solder layer 4 and the steel layer 3.

1. A method for producing multi-walled tubes, in which a metal strip is rolled up to form the multi-walled tube, the metal strip having at least one steel layer, and at least one solder layer being applied to the steel layer, the solder layer consisting at least substantially of metal,
wherein
the solder layer is applied to the steel layer by plasma coating.

2. The method according to claim 1, wherein the solder layer consists of copper or substantially consists of copper.

3. The method according to claim 1, wherein the solder layer is applied to the steel layer without the interposition of a further metal layer.

4. The method according to claim 1, wherein the steel layer has a thickness of 100 to 600 μm.

5. The method according to claim 1, wherein the solder layer is applied to the steel layer by plasma coating with a thickness of 2 to 20 μm.

6. The method according to claim 1, wherein the steel layer is thicker than the solder layer by five times to ten times as thick as the solder layer.

7. The method according to claim 1, wherein the coating is applied without the use of cyanides and/or without the use of nickel.

8. The method according to claim 1, wherein the plasma coating is carried out at normal pressure or atmospheric pressure.

9. The method according to claim 1, wherein the plasma coating is carried out as a physical vapour deposition and/or as a chemical vapour deposition.

10. The method according to claim 1, wherein the material for the solder layer is supplied in a plasma coating device in powder form.

11. The method according to claim 1, wherein the material for the solder layer is converted into the gas phase in the plasma coating device and then deposited on the steel layer as a solder layer.

12. The method according to claim 1, wherein the metal strip consisting of at least the steel layer and the solder layer is rolled up to form a double-walled tube.

13. The method according to claim 1, wherein the steel layer is coated with the solder layer on both surfaces by means of plasma coating.

14. The method according to claim 1, wherein the wall layers of the multi-walled tube are soldered or joined to each other by heating.

15. A multi-walled tube produced using a method according to claim 1 having a rolled-up metal strip, wherein the metal strip has at least one steel layer and at least one solder layer applied to the steel layer by means of plasma coating.

16. The method according to claim 1, wherein the steel layer has a thickness of 200 to 400 μm.

17. The method according to claim 1, wherein the solder layer is applied to the steel layer by plasma coating with a thickness of 3 to 10 μm.
